(19) United States
(12) Patent Application Publication
(10) Pub. No.: US 2015/0017044 A1
(43) Pub. Date: Jan. 15, 2015

(54) ROTARY PISTON ENGINE AND METHOD FOR PRODUCING A ROTARY PISTON ENGINE

(71) Applicants: EADS DEUTSCHLAND GMBH, Ottobrunn (DE); WANKEL SUPER TEC GMBH, Cottbus (DE)

(72) Inventors: Jurgen Steinwandel, Uhldingen-Muhlhofen (DE); Gerd Huber, Munchen (DE); Ernst Sigmund, Cottbus (DE)

(21) Appl. No.: 14/377,017

(22) PCT Filed: Feb. 6, 2013
(86) PCT No.: PCT/EP2013/052283

§ 371 Date: Aug. 6, 2014

(30) Foreign Application Priority Data
Feb. 8, 2012 (DE) 10 2012 101 032.3

(51) Int. Cl. F01C 21/08; C23C 4/08; C23C 14/14; C23C 4/12; C23C 14/32; C23C 24/00; F01C 1/02; C23C 4/10

(52) U.S. Cl. CPC F01C 21/08; F01C 1/02; C23C 4/08; C23C 4/105; C23C 4/124; C23C 4/127; C23C 14/325; C23C 24/00; C23C 14/14
USPC 418/61.2; 427/453; 427/597; 427/580; 427/456

(57) ABSTRACT

A rotary piston engine comprises a stationary housing and a piston movably accommodated in the housing. The housing and the piston form at least one chamber with a chamber surface. At least one partial portion of the chamber surface has a thermal barrier coat for reducing a thermal conductivity of the partial portion of the chamber surface. At least one partial portion of the chamber surface has a metallic spray coat. A method for producing such a rotary piston engine can also be achieved.

The invention relates to a rotary piston engine, in particular a Wankel engine, having a stationary housing and a piston movably accommodated in the housing. The invention further relates to a method for producing such a rotary piston engine.

The invention is part of the field of rotary piston engines and particularly of the field of Wankel engines.

Rotary piston engines have advantages over reciprocating engines if engines with low vibrations and a high power-to-weight ratio are required. The power-to-weight ratio is understood to be the power that an engine is capable of achieving in relation to the weight of the engine. The above-mentioned advantages cause the rotary piston engines to be of interest for operation in aviation. Special applications in aviation, such as auxiliary engines in civilian aircraft, require an operation using kerosene. In contrast to reciprocating engines, the various operating cycles in rotary piston engines run in different portions of the rotary piston engine. So far, the use of kerosene is possible only with difficulties. Among other things, this is due to the fact that in the portion of the rotary piston engine in which combustion takes place, the housing, in contrast to reciprocating engines, is cooled not by other operative processes, but by external cooling. Given a poor thermal insulation of this portion of the rotary piston engine, this entails a low degree of efficiency of the rotary piston engine which, as described above, makes it difficult to enable an operation of the rotary piston engine with kerosene, as this would be required for use in aviation.

DE 10 2007 026 598 A1 describes a rotary piston combustion engine whose housing and rotary piston is provided with a thermal insulation layer.

The invention is based on the object of providing a rotary piston engine with an improved degree of efficiency.

This object is achieved with the rotary piston engine according to claim 1. A method for producing such a rotary piston engine is the subject matter of the co-ordinated claim.

Advantageous embodiments of the rotary piston engine and of the method are the subject matter of the dependent claims.

The rotary piston engine comprises a stationary housing and a piston movably accommodated in the housing, the housing and the piston forming at least one chamber with a chamber surface. In this case, a partial portion of the chamber surface has a thermal barrier coat for reducing a thermal conductivity of the partial portion of the chamber surface. At least one partial portion of the chamber surface has a metallic spray coat.

Preferably, engines in which components that carry out mechanical work substantially only execute rotary movements are provided as rotary piston engines. In particular, a rotary piston engine is supposed to be understood to be a Wankel engine. The above-mentioned chamber is preferably supposed to be understood to be a volume in the rotary piston engine that is enclosed by the piston and the housing. In conventional rotary pistons, several chambers are found. Due to the movement of the piston, the chambers are not constant as regards location, so that, though the chamber surface is always formed by the same part of the piston, the part of the chamber surface provided by the housing changes as the piston rotates. As the piston rotates, the volume of the chamber also changes. In a rotary piston engine, the different operating cycles respectively take place in different portions of the rotary piston engine. This means that a combustible mixture, in particular a fuel-air mixture, is compressed in certain portions of the rotary piston engine and combusted in another portion of the rotary piston engine. This means that in the rotary piston engine, certain portions in which a particularly large amount of heat is generated can be provided with a thermal barrier coat so that the selected portions are thermally better insulated. In particular, this is advantageous in that the energy produced during combustion is dissipated to a lesser extent to the housing of the rotary piston engine, so that a higher temperature level exists in that portion of the rotary piston engine where the combustion occurs. This leads to an improved combustion of the combustible mixture, which results in a higher thermodynamic degree of efficiency of the rotary piston engine, which preferably leads to the reduction of the specific fuel consumption. That means that the energy produced during combustion is preferably converted better into mechanical rotational energy of the piston of the rotary piston engine. Thus, the rotary piston engine preferably has an improved degree of efficiency.

Another preferred advantage of the rotary piston engine is that the exhaust gases, that is, the combusted combustible mixture of the rotary piston engine, are also warmer as compared with conventional rotary piston engines. The heat in the exhaust gases can be used subsequently for other purposes. In conventional rotary piston engines, the housing has to be cooled to a greater extent due to the lack of a thermal barrier coat, so that this heat does not result in a higher combustion temperature and to more heat in the exhaust gas. This means that in conventional rotary piston engines, the heat is transferred to the cooling medium of the cooling system and is thus no longer available to the rotary piston engine.

Preferably, a housing surface forming a part of the chamber surface comprises a first, a second, a third and a fourth partial housing portion. Also preferably, a first partial housing portion is disposed in an inlet portion of the housing for admitting a combustible mixture, a second partial housing portion is disposed in a compression portion of the housing for compressing the combustible mixture, a third partial housing portion is disposed in a combustion portion of the housing for combusting the combustible mixture, and a fourth partial housing portion is disposed in an outlet portion of the housing for discharging the combusted combustible mixture. Preferably, the thermal barrier coat is disposed in the third partial housing portion and/or the fourth partial housing portion. This means that, preferably, the thermal barrier coat is disposed in those partial housing portions that are adjacent to the portions of the rotary piston engine in which the combustion or the discharge of the combusted combustible mixture occurs. Thus, an arrangement of a thermal barrier coat is preferably particularly effective in these portions because temperatures are high there.

Consequently, a cooling device for cooling the housing is preferably disposed in the third and/or fourth partial housing portion. As was described above, a preferred advantage of the invention is that the cooling device, compared with conventional rotary piston engines, has to cool the housing of the rotary piston engine to a lesser extent because the thermal barrier coat reduces a heat propagation through the housing of the rotary piston engine.

Also preferably, a thermal barrier coat is also provided on the surface of the piston. In particular, this prevents a heat loss via the piston surface. This preferably also helps to increase the degree of efficiency, as described above, of the rotary piston engine.

It is preferred that the thermal barrier coat has a ceramic coat, in particular an oxide ceramic coat, and more particularly, a zirconium oxide coat.

The above-mentioned coats are advantageously capable of withstanding high temperatures so that they are used, for example, in the region of the combustion chamber or of the high-pressure turbine of an aircraft turbine. There, they primarily serve for the thermal protection of the materials located underneath the coat. The empirical values obtained can advantageously be transferred onto the rotary piston engine, all the more since a thermal insulation is to be obtained by means of the thermal barrier coat also in the case of the rotary piston engine.

Also preferably, the zirconium oxide coat is at least partially stabilized by means of yttrium. In particular, the addition of yttrium serves for making the zirconium oxide coat more durable. Preferably, this increases the life of the thermal barrier coat.

It is another preferred embodiment of the thermal barrier coat that the thermal barrier coat has a lanthanum aluminate coat or a hexaaluminate coat.

These two coats advantageously also have the above-mentioned properties of the thermal barrier coat.

It is preferred that the oxide ceramic coat is applied to the at least one partial portion of the chamber surface by means of high-speed flame spraying, laser powder coating or arc spraying, and/or that the lanthanum aluminate coat or the hexaaluminate coat is applied to the at least one partial portion of the chamber surface by means of an atmospheric high-temperature coating method, in particular by plasma spraying, high-speed flame spraying, laser powder coating or arc spraying.

The above-mentioned coating processes are known in principle, so that the details of carrying them out need not be addressed herein. Nowadays, laser powder coating is frequently used in “rapid prototyping”. DE 10 2007 018 126 A1 describes laser powder coating in more detail. In particular, it is possible to generate the coat from a graphics file, in particular a CAD file, so that complicated shapes can also be obtained. The above-mentioned thermal coating methods advantageously enable a uniform application of the thermal barrier coat onto the chamber surface so that a thermal barrier coat of a substantially uniform thickness can be produced on the chamber surface. This is advantageous, in particular, in that a smooth or flat thermal barrier coat is produced that enables a uniform contact with the piston or, in case of an application on the piston, with the housing, so that the friction between the housing and the piston can be reduced. Furthermore, a uniform application of the thermal barrier coat preferably causes the thermal insulation to be of substantially the same size in those portions in which the thermal barrier coat is applied. No regions in the housing are thus created that are particularly hot and thereby cause an irregular expansion of the housing.

It is further preferred that the metallic spray coat has a corrosion coat and/or a tribological coat.

The metallic spray coat preferably serves for preventing a corrosion of the chamber surface (corrosion coat) and/or for reducing the friction between the housing and the piston (tribological coat). A first preferred advantage is a longer service life of the housing surface due to reduced corrosion, so that fewer areas with damage to the housing surface form. This preferably reduces, particularly in advanced stages of the operation of the rotary piston engine, the friction between the piston and the housing. A second preferred advantage of the application of the metallic spray coat preferably is a reduced friction between the housing and the piston. Preferably, this can be achieved by the metallic spray coat directly reducing the friction between the housing and the piston, or by the friction between the housing and the piston being reduced by the metallic spray coat advantageously providing for a uniform distribution of lubricants on the chamber surface.

Preferably, the metallic spray coat has an AL:Ni—Al coat.

Also preferably, the metallic spray coat is applied by means of an atmospheric high-temperature coating method, in particular by plasma spraying, flame spraying, high-speed flame spraying, laser powder coating or arc spraying.

The above-mentioned coating processes preferably have the same advantages as the coating processes for applying the thermal barrier coat have.

It is preferred that the metallic spray coat forms a surface of the chamber surface and the thermal barrier coat is disposed underneath the metallic spray coat.

This preferred application of the thermal barrier coat and the metallic spray coat achieves a reduction of the thermal conductivity through the housing and also a reduction between the housing and the piston at the same time. Both effects advantageously increase the degree of efficiency of the rotary piston engine.

Preferably, the rotary piston engine is configured for the combustion of kerosene and/or diesel fuel.

Due to the above-mentioned improvements of the degree of efficiency of the rotary piston engine, it is now preferably possible to also combust kerosene and/or diesel fuel in the rotary piston engine.

It is preferred that the rotary piston engine is disposed between a turbocharger and an exhaust pipe, the rotary piston engine having an exhaust gas heat utilization device, in particular an expansion turbine.

The exhaust gas heat utilization device preferably serves for converting the heat of the exhaust gas either into mechanical or electrical work and thus utilize it. Because the thermal barrier coat, as described above, reduces the thermal conductivity of the housing, more heat preferably remains in the exhaust gas, so that more heat from the exhaust gas can be utilized.

A method for producing a rotary piston engine is characterized by coating at least one partial portion of the chamber surface of the rotary piston engine as it was described above with a thermal barrier coat and by coating the first partial portion and/or a second partial portion of the chamber surface with the metallic spray coat.

That means that a first partial portion, preferably the third and/or fourth partial housing portion, is provided with the thermal barrier coat and the metallic spray coat. The first and second partial housing portions, the inlet portion and the compression portion, are preferably provided only with the metallic spray coat. This preferably offers the advantage that the combustion portion and the outlet portion, in which combustion heat is produced, are thermally insulated by the thermal barrier coat, whereas no thermal barrier coat is disposed in the inlet portion and the compression portion, in which no combustion heat is produced. By omitting the thermal barrier coat in the inlet portion and the compression portion, the production costs can preferably be reduced. The preferred application of the metallic spray coat on the entire housing surface offers the preferred advantage that the friction between the housing and the piston can be reduced throughout an entire rotation of the piston.

The application of the thermal barrier coat and/or the metallic spray coat onto the piston surface is also preferred.

It is preferred that a method for producing a rotary piston engine is characterized in that at least the first partial portion of the chamber surface is coated with an oxide coat, in particular a zirconium oxide coat partially stabilized by means of yttrium, the oxide coat preferably being applied by means of high-speed flame spraying, laser powder coating or arc spraying, and/or that at least the first partial portion of the chamber surface is coated with one of a lanthanum aluminate coat or a hexaaluminate coat, the lanthanum aluminate coat or the hexaaluminate coat advantageously being applied by means of an atmospheric high-temperature coating method, in particular by plasma spraying, flame spraying, high-speed flame spraying, laser powder coating or arc spraying.

It is preferred that a method for coating a rotary piston engine is characterized in that the first and/or the second partial portions of the chamber surface is coated with an AL:Ni-AL coat, the AL:Ni-AL coat preferably being applied by means of an atmospheric high-temperature coating method, in particular by plasma spraying, flame spraying, high-speed flame spraying, laser powder coating or arc spraying.

The above-mentioned methods have the above-mentioned advantages.

Advantageous embodiments are the subject matter of the dependent claims.

The invention will be explained in more detail below with reference to the attached drawings. In the drawings:

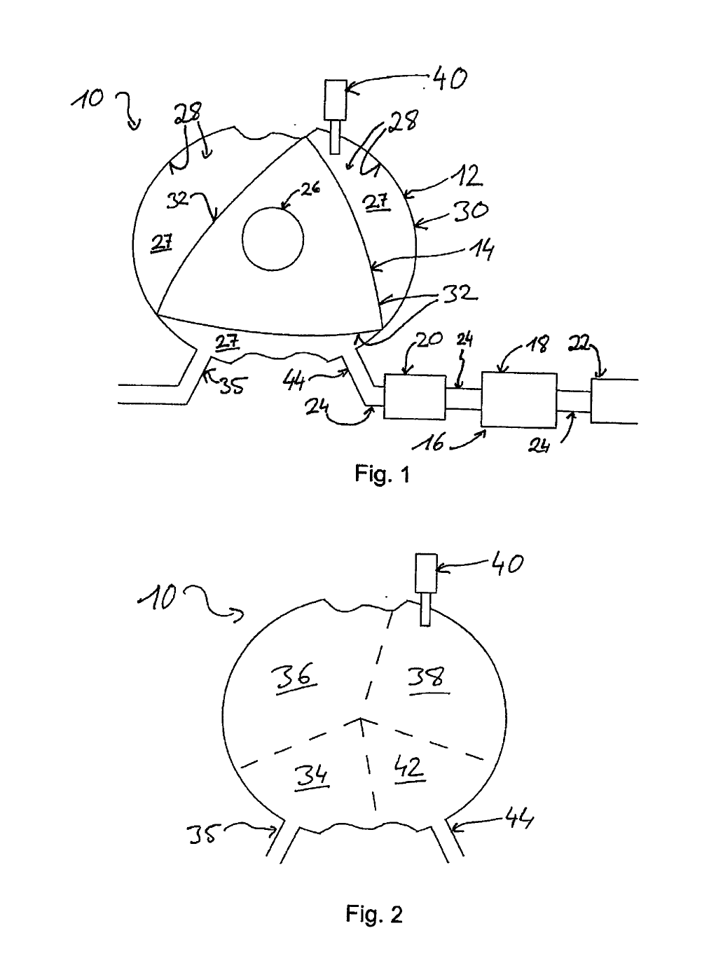

FIG. 1 shows a cross section through a rotary piston engine;

FIG. 2 shows a cross section through the rotary piston engine from FIG. 1 without a piston;

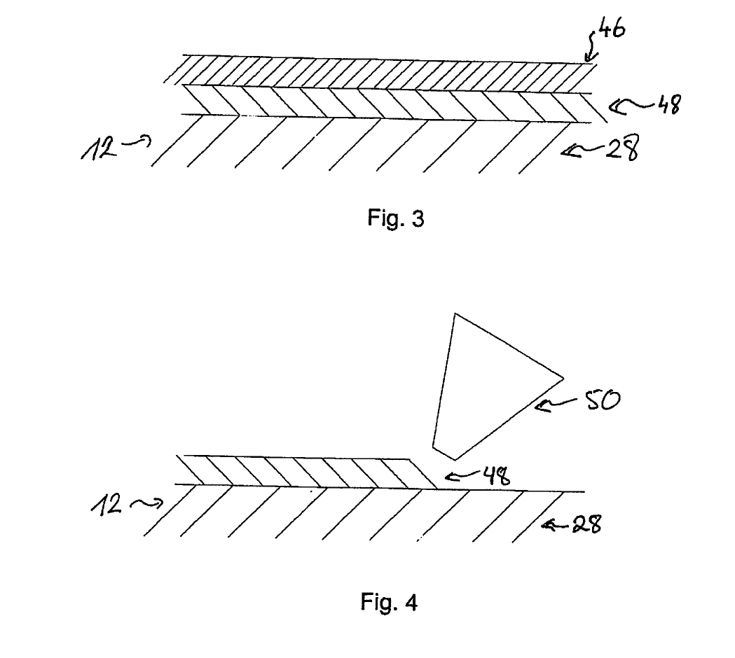

FIG. 3 shows a cross section through a housing surface of the rotary piston engine from FIG. 1 with a thermal barrier coat and a metallic spray coat; and

FIG. 4 shows a cross section of the housing surface from FIG. 3 in a snapshot during a method for producing a rotary piston engine.

A preferred rotary piston engine 10 is now described with reference to FIG. 1.

The rotary piston engine 10 has a housing 12 and a piston 14. Furthermore, an exhaust gas heat utilization device 16 in the form of an expansion turbine 18 is allocated to the rotary piston engine 10. The rotary piston engine 10 is disposed between a turbocharger 20 and an exhaust pipe 22 and is connected to the turbocharger 20 and the exhaust pipe 22 via pipes 24.

The piston 14 is rotatably supported in the housing 12 via a shaft 26. The shaft 26 is configured in such a manner that an eccentric movement of the piston 14 causes a rotation of the shaft 26. Since the mode of operation of a rotary piston engine 10 is generally known, the mode of operation of the rotary piston engine 10 is not to be addressed in more detail herein.

The piston 14 and the housing 12 divide the interior of the rotary piston engine 10 into three chambers 27 that separate the individual chambers 27 from each other by means of seals that are not shown. Due to the rotation of the piston 14, the chambers 27 are not stationary, so that a chamber surface of the chamber 27 is formed by different portions of a housing surface 28 of the housing 12. The boundary of the chamber 27 on the side of the piston 14 always constitutes a piston wall 32 of the piston 14; that is, the chamber 27 is always delimited by the same piston wall 32 over the course of a rotation of the piston 14.

The housing 12 has the housing surface 28. In FIGS. 1 and 2, the housing surface 28 is disposed parallel to the cross-sectional plane of the rotary piston engine 10 and at an inner wall 30 of the housing 12. In the embodiment shown in FIG. 1, the piston 14 has three piston walls 32.

The piston 14 and the housing 12 are preferably fabricated from a metal or a metal alloy.

As can be seen better in FIG. 2, the housing surface 28 can be divided into four partial portions. A first partial portion 34 is disposed in the vicinity of an inlet 36. A combustible mixture, in this case kerosene, in particular, is introduced into the rotary piston engine 10 through the inlet 36. A second partial housing portion 36 is disposed in a clockwise direction, which is also the direction of rotation of the piston 14. In that portion, the combustible mixture is compressed by the piston 14; that is, the volume of the chamber 27 is made smaller in this portion. This portion is also referred to as compression portion. In a third partial housing portion 38, which is disposed in the vicinity of a spark plug 40, the combustible mixture is combusted. A fourth partial housing portion 42 is disposed in the vicinity of an outlet 44. The combusted combustible mixture is discharged into the outlet 44 by the piston 14. The division of the housing surface 28 into the first 34, the second 36, the third 38 and the fourth partial housing portion 42 is merely an example, wherein the boundaries between the individual partial portions 34, 36, 38, 42 cannot be drawn exactly. That means that it cannot be exactly determined, for example, where the inlet portion ends and the compression portion begins.

In the preferred embodiment, only a metallic spray coat 46 is disposed on the housing surface 28 in the first 34 and second partial housing portions 36. In contrast, the metallic spray coat 46 and a thermal barrier coat 48 are disposed in the third 38 and the fourth partial housing portion 42. The respective arrangement of the thermal barrier coat 48 and of the metallic spray coat 46 on the housing surface 28 is apparent from FIG. 3. First, the thermal barrier coat 48 is located on the housing surface 28. The metallic spray coat 46 is located upon the thermal barrier coat 48. That means the metallic spray coat 46 is in contact with other parts of the rotary piston engine 10 or with the combustible mixture. The thermal barrier coat 48 is preferably completely covered by the metallic spray coat 46.

The thermal barrier coat 46 is preferably produced from oxide ceramics, in particular zirconium oxide ceramics preferably stabilized by yttrium. Alternatively, the thermal barrier coat is made from a lanthanum aluminate coat or a hexaaluminate coat. Preferably, the metallic spray coat 46 is made from an AL:Ni—Al alloy.

The mode of operation of the rotary piston engine 10 is to be illustrated hereinafter. Since the mode of operation of a rotary piston engine 10 is generally known, the preferred effect of the thermal barrier coat 48 and the metallic spray coat 46 is to be addressed herein with preference.

The combustible mixture is admitted by the turbocharger 20 via the pipe 24 on the inlet 36 in the region of the first partial housing portion 34. Due to the rotation of the piston 14 and its eccentric movement, the combustible mixture is compressed in the region of the second partial housing portion 36 (that is, the volume of the chamber 27 is made smaller by the eccentric movement of the piston 14), and combusted in the region of the third partial housing portion 38 after an ignition by the spark plug 40. Due to the combustion of the combustible mixture, the pressure in the chamber 27 rises, which causes an enlargement of the volume of the chamber 27. Because of the arrangement and support of the piston 14, this results in a rotation of the piston 14. In the region of the fourth partial housing portion 42, the combusted combustible mixture is supplied at the outlet 44 via a pipe 24 to the exhaust gas heat utilization device 16, which supplies the combusted combustible mixture to an exhaust pipe 22. The exhaust gas heat utilization device 16 abstracts heat from the combusted combustible mixture and thus recovers mechanical or electrical energy.

The thermal barrier coat 48 in the region of the third partial housing portion 38 and of the fourth partial housing portion 42 reduces the thermal conductivity of the housing 12 in these partial portions. Thus, less heat is dissipated to the housing 12 during the combustion, whereby the combustion temperature of the combustion in the region of the third partial housing portion 38 and the heat of the combusted combustible mixture increases. The increased combustion temperature increases the degree of efficiency of the rotary piston engine 10. The increased temperature of the combusted combustible mixture increases the energetic yield of the exhaust gas heat utilization device 16 and thus also the degree of efficiency of the rotary piston engine 10.

The metallic spray coat 46 reduces the friction between the piston 14 and the housing 12. Through seals that are not shown, the piston 14 is in permanent contact with the housing surface 28. The seals serve for sealing the chambers 27 well. A reduction of the friction between the piston 14 and the housing surface 28 increases the degree of efficiency.

The method for producing a rotary piston engine is now to be described with reference to FIG. 4. The housing surface 28 of the housing 12 is preferably applied onto the housing surface 28 by high-speed flame spraying, laser powder coating or arc spraying. For this purpose, a nozzle 50 is brought into the vicinity of the housing surface 28 and material particles of the material from which the thermal barrier coat 48 is made are accelerated towards the housing surface 28. Due to the velocity and the heat of the material particles, the material particles form on the housing surface 28 a crystalline coat forming the thermal barrier coat 48. Subsequent thereto, the metallic spray coat 46 can be applied onto the thermal barrier coat 48 in a similar manner. Preferably, an adhesion promoter is applied onto the housing surface 28 before the thermal barrier coat 48 is applied, in order to improve the adhesion of the thermal barrier coat 48.

Rotary piston engines 10 have important advantages over reciprocating engines, particularly if low vibrations and a high power-to-weight ratio are required. Thus, these engines are basically well-suited for the field of aviation. Special applications in aviation (e.g. drive units of UAVs, replacement turbine APUs in civilian aircraft) require an operation using kerosene. It is known that diesel-operated reciprocating engines can be operated with kerosene without any major problems. In the case of rotary piston engines 10, this is more difficult but basically possible. What is necessary is an improved degree of efficiency of the rotary piston engines 10 (optimization of combustion).

Thermal barrier coats 48 (TBC) are one possible option for optimizing combustion in rotary piston engines 10. The coating of components in aviation turbines is the prior art. Thermal barrier coat are used here particularly in the region of the combustion chamber and the high-pressure turbine. Here, the function is primarily the thermal protection of the high-temperature materials (Ni- and Co-based alloys).

Furthermore, it is known that heat insulation coats for conventional reciprocating engines were investigated. A serial application is not known.

Compared with a reciprocating engine, a rotary piston engine 10 is thermodynamically characterized in that the different operating cycles run in individual chambers. Thus, no classic scavenging conditions are provided as in a reciprocating engine, and a thermal barrier coat 48 can be specifically applied in the “combustion chamber” and also in the “expansion chamber” in order to optimize the thermal balance of the machine. For this purpose, the portions are coated with typical thermal barrier coats 48, e.g. yttrium-stabilized zirconium oxide (methods: the thermal powder spraying technologies, such as plasma spraying, flame spraying and high-speed flame spraying). For example, the yttrium-stabilized zirconium oxide coat can be additionally covered with a metallic spray coat (Al:Ni—Al) in order to improve the running properties.

The advantages of a thermal barrier coat 48 in rotary piston engines 10 are as follows:
Coating of the “combustion chamber” leads to a higher temperature level and thus to an improved combustion, resulting in a higher thermodynamic degree of efficiency (reduction of the specific fuel consumption)
Coating of the “expansion chamber” leads to a reduction of the heat input into the external cooling medium (generally water). Therefore, more utilizable heat is available in the exhaust gas, which can be utilized by means of an additional expansion turbine either as mechanical or electrical energy (in contrast to the heat loss in the cooling medium).

An adhesion promoter can be provided between the thermal barrier coat 48 and the combustion/expansion chamber. It is one aspect of the invention that the thermal barrier coat 48 is a zirconium oxide partially stabilized with yttrium, which is applied by means of a method such as high-speed flame spraying or arc spraying. It is another aspect that the thermal barrier coat 48 is a lanthanum aluminate or a hexaaluminate coat. Here, the methods for applying the thermal barrier coat 48 are atmospheric high-temperature coating processes (plasma spraying, high-speed flame spraying, flame spraying, arc spraying etc.).

It is a second aspect of the invention that the thermal barrier coat 48, which is made either from a zirconium oxide partially stabilized with yttrium or from lanthanum/hexaaluminate, is additionally provided with an Al:Ni—Al. The methods for applying the metallic spray coat 46 are atmospheric high-temperature coating processes (plasma spraying, high-speed flame spraying, flame spraying, arc spraying etc.). In this case, the metallic spray coat 46 is a corrosion coat or a tribological coat and offers improved running properties of the piston and an additional protection of the thermal barrier coat 46.

In another aspect of the invention, the expansion turbine 18 is disposed between the turbocharger 20 and the exhaust pipe 22.

### REFERENCE SIGN LIST

10 Rotary piston engine
12 Housing
14 Piston
16 Exhaust gas heat utilization device
18 Expansion turbine
20 Turbocharger
22 Exhaust pipe
24 Pipe
26 Shaft
27 Chamber
28 Housing surface
30 Housing wall
32 Piston wall
34 First partial housing portion
35 Inlet
35 Second partial housing portion
38 Third partial housing portion
40 Spark plug
42 Fourth partial housing portion
44 Outlet
46 Metallic spray coat
48 Thermal barrier coat
50 Nozzle

1. A rotary piston engine, comprising
a stationary housing; and
a piston movably accommodated in the housing, the housing and the piston forming at least one chamber with a chamber surface, at least one partial portion of the chamber surface having a thermal barrier coat configured to reduce a thermal conductivity of the partial portion of the chamber surface, and at least one partial portion of the chamber surface having a metallic spray coat.

2. The rotary piston engine according to claim 1, wherein
the thermal barrier coat has an oxide ceramic coat including zirconium oxide.

3. The rotary piston engine according to claim 2, wherein
the zirconium oxide is at least partially stabilized by yttrium.

4. The rotary piston engine according to claim 1, wherein
the thermal barrier coat has a lanthanum aluminate coat or a hexaaluminate coat.

5. The rotary piston engine according to claim 2, wherein at least one of the following
the oxide ceramic coat is applied to the at least one partial portion of the chamber surface by high-speed flame spraying, laser powder coating or arc spraying; and
the lanthanum aluminate coat or the hexaaluminate coat is applied to the at least one partial portion of the chamber surface by an atmospheric high-temperature coating method including plasma spraying, high-speed flame spraying, laser powder coating or arc spraying.

6. The rotary piston engine according to claim 1, wherein
the metallic spray coat has at least one of a corrosion coat and a tribological coat.

7. The rotary piston engine according to claim 1, wherein
the metallic spray coat has an Al:Ni—Al coat.

8. The rotary piston engine according to claim 1, wherein
the metallic spray coat is applied by an atmospheric high-temperature coating method including plasma spraying, flame spraying, high-speed flame spraying, laser powder coating or arc spraying.

9. The rotary piston engine according to claim 1, wherein
the metallic spray coat forms a surface of the chamber surface and the thermal barrier coat (48) is disposed underneath the metallic spray coat.

10. The rotary piston engine according to claim 1, wherein
the rotary piston engine is configured for combustion of at least one of kerosene and diesel fuel.

11. The rotary piston engine according to claim 1, wherein
the rotary piston engine is disposed between a turbocharger and an exhaust pipe, and
the rotary piston engine further comprises an exhaust gas heat utilization device including an expansion turbine.

12. A method for producing a rotary piston engine according to claim 1, comprising
coating at least one partial portion of the chamber surface of the rotary piston engine with the thermal barrier coat; and
coating at least one of the first partial portion and another partial portion of the chamber surface with the metallic spray coat.

13. The method for producing a rotary piston engine according to claim 12, further comprising at least one of the following
coating at least the partial portion of the chamber surface with an oxide coat including zirconium oxide coat partially stabilized by yttrium, the coating including high-speed flame spraying, laser powder coating or arc spraying; and
coating at least the partial portion of the chamber surface with a lanthanum aluminate coat or a hexaaluminate coat by an atmospheric high-temperature coating process including plasma spraying, flame spraying, high-speed flame spraying, laser powder coating or arc spraying.

14. The method for producing a rotary piston engine according to claim 12, further comprising
coating at least one of the partial portion and the another partial portion of the chamber surface with an AL:Ni-AL coat by an atmospheric high-temperature coating process including plasma spraying, flame spraying, high-speed flame spraying, laser powder coating or arc spraying.

15. The method for producing a rotary piston engine according to claim 13, further comprising
coating at least one of the partial portion and the another partial portion of the chamber surface with an AL:Ni-AL coat by an atmospheric high-temperature coating process including plasma spraying, flame spraying, high-speed flame spraying, laser powder coating or arc spraying.

16. The rotary piston engine according to claim 2, wherein
the thermal barrier coat has a lanthanum aluminate coat or a hexaaluminate coat.

17. The rotary piston engine according to claim 3, wherein at least one of the following
the oxide ceramic coat is applied to the at least one partial portion of the chamber surface by high-speed flame spraying, laser powder coating or arc spraying; and
the lanthanum aluminate coat or the hexaaluminate coat is applied to the at least one partial portion of the chamber surface by an atmospheric high-temperature coating method including plasma spraying, high-speed flame spraying, laser powder coating or arc spraying.

18. The rotary piston engine according to claim 2, wherein
the metallic spray coat has at least one of a corrosion coat and a tribological coat.

19. The rotary piston engine according to claim 2, wherein
the metallic spray coat has an Al:Ni—Al coat.

20. The rotary piston engine according to claim 2, wherein
the metallic spray coat is applied by an atmospheric high-temperature coating method including plasma spraying, flame spraying, high-speed flame spraying, laser powder coating or arc spraying.
